(19) United States
(12) Patent Application Publication
(10) Pub. No.: US 2025/0308612 A1
(43) Pub. Date: Oct. 2, 2025

(54) ADAPTIVE MEMORY ERASING FOR MEMORY DEVICES WITH CENTRAL ROW DECODERS

(71) Applicant: Micron Technology, Inc., Boise, ID (US)

(72) Inventors: Yu-Chung Lien, San Jose, CA (US); Zhenming Zhou, San Jose, CA (US)

(21) Appl. No.: 19/089,945

(22) Filed: Mar. 25, 2025

Related U.S. Application Data
(60) Provisional application No. 63/571,419, filed on Mar. 28, 2024.

(51) Int. Cl. G11C 29/18

(52) U.S. Cl. CPC G11C 29/18; G11C 2029/1802

(57) ABSTRACT

Methods, systems, and apparatuses include receiving, from a host system, an erase command for a memory device. A portion of memory of the memory device is determined using an address of the erase command. It is determined to include a first subportion of the portion of memory in an erase operation and to exclude a second subportion of the portion of memory in the erase operation. Trim settings are selected in response to the determination to include the first subportion and exclude the second subportion. The erase operation is executed on the first subportion but not the second subportion based on the trim settings.

### CROSS-REFERENCE TO RELATED APPLICATION

The present application claims the benefit of U.S. Provisional Patent Application No. 63/571,419 filed on Mar. 28, 2024, which is incorporated by reference herein in its entirety.

### TECHNICAL FIELD

The present disclosure generally relates to adaptive memory erasing, and more specifically, relates to adaptive memory erasing for memory devices with central row decoders.

### BACKGROUND ART

A memory subsystem can include one or more memory devices that store data. The memory devices can be, for example, non-volatile memory devices and volatile memory devices. In general, a host system can utilize a memory subsystem to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory subsystem in accordance with some embodiments of the present disclosure.

FIG. 2 illustrates another example computing system that includes an adaptive memory erasing component in accordance with some embodiments of the present disclosure.

FIG. 3 illustrates another example computing system that includes an adaptive memory erasing component in accordance with some embodiments of the present disclosure.

FIG. 4 is a flow diagram of an example method to adaptively erase memory devices with central row decoders in accordance with some embodiments of the present disclosure.

FIG. 5 is another flow diagram of an example method to adaptively erase memory devices with central row decoders in accordance with some embodiments of the present disclosure.

FIG. 6 is a block diagram of an example computer system in which embodiments of the present disclosure may operate.

### DETAILED DESCRIPTION

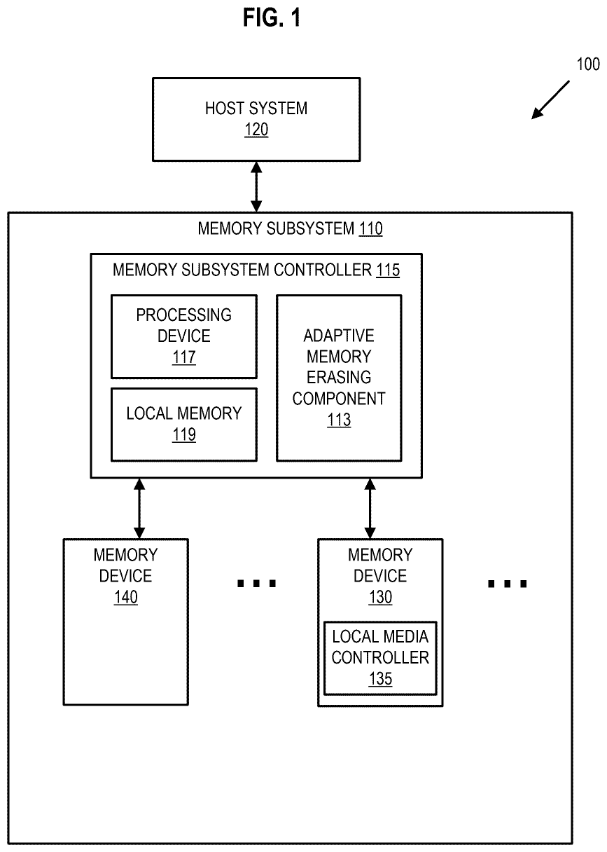

Aspects of the present disclosure are directed to adaptive erasing for memory devices with central row decoders. A memory subsystem can be a storage device, a memory module, or a hybrid of a storage device and memory module. Examples of storage devices and memory modules are described below in conjunction with FIG. 1. In general, a host system can utilize a memory subsystem that includes one or more components, such as memory devices that store data. The host system can provide data to be stored at the memory subsystem and can request data to be retrieved from the memory subsystem.

A memory device can be a non-volatile memory device. A non-volatile memory device is a package of one or more dice. One example of non-volatile memory devices is a negative-and (NAND) memory device. Other examples of non-volatile memory devices are described below in conjunction with FIG. 1. The dice in the packages can be assigned to one or more channels for communicating with a memory subsystem controller. Each die can consist of one or more planes. Planes can be grouped into logic units identified by a logical unit number (LUN). For some types of non-volatile memory devices (e.g., NAND memory devices), each plane consists of a set of physical blocks, which are groups of memory cells to store data. A cell is an electronic circuit that stores information.

Depending on the cell type, a cell can store one or more bits of binary information, and has various logic states that correlate to the number of bits being stored. The logic states can be represented by binary values, such as “0” and “1”, or combinations of such values. There are various types of cells, such as single-level cells (SLCs), multi-level cells (MLCs), triple-level cells (TLCs), quad-level cells (QLCs), and penta-level cells (PLCs). For example, an SLC can store one bit of information and has two logic states while a QLC can store eight bits of information and has sixteen logic states.

Various memory access operations can be performed on the memory cells. Data can be written to, read from, and erased from memory cells. Memory cells are formed around shared channel regions (e.g., regions between sources and drains of memory cells) which are formed as pillars of semiconductor material (e.g., polysilicon). Memory cells can be grouped into a write unit, such as a page. For some types of memory devices, a page is the smallest write unit. A page size represents a particular number of cells of a page. Memory cells can be formed into strings with tiers of memory cells stacked source to drain between a source line (SRC) or a source-side select gate (SGS) and a drain-side select gate (SGD). These strings can be arranged into data lines (strings sharing a bitline) in one dimension and into pages in the other dimension. Within each of these pages, each tier of these memory cells represents a row and each string represents a column. For some types of memory devices (e.g., NAND), memory cells can be grouped into an erase unit, such as a block. Data can be written to a block, page-by-page. For example, a block may be subdivided into 64 separately programmable pages. Data is erased at the block level—i.e., conventionally, portions of a block cannot be erased.

One or more decoders may be included in blocks of a memory device. For example, a combination of a row decoder and a column decoder can be used to map addresses to pages of memory. For example, row decoders can identify rows (e.g., tiers) of pages while column decoders can identify columns (e.g., strings). A row decoder receives row addresses as inputs and selects particular word lines in a page based on the row addresses. The row decoder transmits signals (e.g., program data) to the selected word lines. Row decoders are conventionally placed on the edges of a page (e.g., the right or left) with signals from the row decoders transmitted across the page (e.g., from the left to right or from the right to left).

In conventional memory systems, defects in memory devices increase over time, leading to unreliability in memory operations for these memory devices. Indeed, as memory devices include more and more storage and higher densities of storage, these memory devices are subject to higher risks for defects and unreliability. In order to account for these defects, conventional systems employ system management for partially good blocks (PGBs) for memory devices with single edge row decoders (e.g., a row decoder placed on the edge of a page). System management for these PGBs identifies when a block, which is divided into subportions (e.g., the block spans two decks/different planes of memory), and has defects concentrated in one of the decks. Accordingly, the system management can differentiate between the good and bad decks of memory blocks and maintain the bad decks in an erased state to avoid inefficiencies caused by performing memory operations on known bad decks, prevent any further degradation of the known bad decks, and prevent potential corruption of the good decks. Because these decks belong to the same memory block, wordlines for different decks still neighbor each other and cause interference when executing operations on one deck but not the other. Additionally, when using these system management techniques, conventional memory systems must account for differences in voltage distributions which arise when only using part of a block (e.g., a deck). For example, due to mismatches between the string current between full blocks (e.g., memory blocks with all good parts) and PGBs with good decks and back decks, read levels need to be adjusted for each block resulting in increased power consumption and increased memory operation execution time.

Aspects of the present disclosure address the above and other deficiencies by adaptively erasing memory devices with central row decoders. For example, the memory subsystem uses a memory device architecture with a row decoder placed within a page/memory block (e.g., in the center of pages of a memory block). Memory systems implementing this central row decoder architecture transmit signals from the row decoder within the page to the edges of the page. For example, a row decoder located in the center of a page transmits signals from the center to the left and the center to the right. Additionally, the central row decoder provides a physical isolation between the two sides, resulting in significantly less interference than a conventional deck implementation. Using central row decoders also reduces word line loading through this physical isolation. For example, because each side of the wordline is half the size of conventional systems, the time it takes for the wordlines to ramp and stabilize is reduced, thereby reducing the overall time of program and read operations. Because memory blocks are apportioned horizontally (e.g., pages divided by the central row decoder) rather than vertically (e.g., blocks divided into decks), a partial block can use both upper and lower decks of the memory device and therefore includes full strings. This results in the same string current for a single portion of the memory block and therefore removes the need to adjust read levels due to the mismatches in string current between full blocks and PGBs. The memory system can determine, based on memory addresses of erase commands from the host system, whether the entirety of the block should be erased or whether only part of the block should be erased. For example, the memory system can use a PGB implementation to determine whether a target memory address is a PGB and if so, which portion of the block (e.g., left of the central row decoder or right of the central row decoder) should be erased. When erasing a PGB, the memory system can change settings of the erase operation to prevent the erase operation from executing on the non-designated portion. This allows the memory system to save energy and time by foregoing execution of the erase operation on the bad parts and prevents any further damage to the bad parts. Furthermore, even for memory portions that are fully good, the memory system can erase smaller subportions, allowing for greater flexibility in memory device storage.

FIG. 1 illustrates an example computing system 100 that includes a memory subsystem 110 in accordance with some embodiments of the present disclosure. The memory subsystem 110 can include media, such as one or more volatile memory devices (e.g., memory device 140), one or more non-volatile memory devices (e.g., memory device 130), or a combination of such.

A memory subsystem 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory subsystems 110. In some embodiments, the host system 120 is coupled to different types of memory subsystems 110. FIG. 1 illustrates one example of a host system 120 coupled to one memory subsystem 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processing device such as a processor chipset and a software stack executed by the processor chipset. The processor chipset can include one or more cores, one or more caches, a memory controller (e.g., NVDIMM controller), and/or a storage protocol controller (e.g., a peripheral component interconnect express (PCIe) controller, a serial advanced technology attachment (SATA) controller). The host system 120 uses the memory subsystem 110, for example, to write data to the memory subsystem 110 and read data from the memory subsystem 110.

The host system 120 can be coupled to the memory subsystem 110 via a physical host interface. Examples of a physical host interface include, but are not limited to, a SATA interface, including a mini-SATA (mSATA) interface, a PCIe interface, including a mini PCIe (mPCIE) interface, a Non-Volatile Memory Express (NVMe) interface, a universal serial bus (USB) interface, an a Fibre Channel, Serial Attached SCSI (SAS), a Small Computer System Interface (SCSI), a double data rate (DDR) memory bus, a dual in-line memory module (DIMM) interface (e.g., DIMM socket interface that supports Double Data Rate (DDR)), an Advanced Host Controller (AHCI) interface, an Open NAND Flash Interface (ONFI) interface, a Double Data Rate (DDR) interface, a Low Power Double Data Rate (LPDDR) interface, any other interface, and/or combinations of these interfaces. The physical host interface can be used to transmit data between the host system 120 and the memory subsystem 110. The host system 120 can further utilize an NVMe interface to access components (e.g., memory devices 130 and 140) when the memory subsystem 110 is coupled with the host system 120 by the PCIe interface. The physical host interface can provide an interface for passing control, address, data, and other signals between the memory subsystem 110 and the host system 120. FIG. 1 illustrates a memory subsystem 110 as an example. In general, the host system 120 can access multiple memory subsystems via the same communication connection, multiple separate communication connections, and/or a combination of communication connections.

The memory devices 130 and 140 can include any combination of the different types of non-volatile memory devices and/or volatile memory devices. The volatile memory devices (e.g., memory device 140) can be, but are not limited to, random-access memory (RAM), such as dynamic random-access memory (DRAM), synchronous dynamic random-access memory (SDRAM), video random-access memory (VRAM), and cache memory.

Some examples of non-volatile memory devices (e.g., memory device 130) include negative-and (NAND) type flash memory devices and write-in-place type memory devices, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. NAND type flash memory includes, for example, two-dimensional NAND (2D NAND) and three-dimensional NAND (3D NAND).

Although non-volatile memory devices such as NAND type memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random-access memory (FeRAM), magneto random-access memory (MRAM), Spin Transfer Torque (STT)-MRAM, nano-RAM (NRAM), silicon-oxide-nitride-oxide-silicon (SONOS) memory, conductive bridging RAM (CBRAM), resistive random-access memory (RRAM), oxide based RRAM (OxRAM), negative-or (NOR) flash memory, and erasable programmable read-only memory (EPROM), including electrically erasable programmable read-only memory (EEPROM).

A memory subsystem controller 115 (or controller 115 for simplicity) can communicate with the memory devices 130 to perform operations such as reading data, writing data, or erasing data at the memory devices 130 and other such operations (e.g., in response to commands scheduled on a command bus by controller 115). The memory subsystem controller 115 can include hardware such as one or more integrated circuits and/or discrete components, a buffer memory, or a combination thereof. The hardware can include digital circuitry with dedicated (i.e., hard-coded) logic to perform the operations described herein. The buffer memory of subsystem controller 115 can include any of the volatile or non-volatile memory types mentioned above including combinations thereof. The memory subsystem controller 115 can be a microcontroller, special purpose logic circuitry (e.g., a field programmable gate array (FPGA), an application specific integrated circuit (ASIC), etc.), or another suitable processor.

The memory subsystem controller 115 can include a processing device 117 (processor) configured to execute instructions stored in memory subsystem 110 (e.g., stored in a local memory 119). In some examples, the local memory 119 of the memory subsystem controller 115 includes an embedded memory configured to store instructions for performing various processes, operations, logic flows, and routines that control operation of the memory subsystem 110, including handling communications between the memory subsystem 110 and the host system 120.

In some embodiments, the local memory 119 can include memory registers storing memory pointers, fetched data, etc. The local memory 119 can also include read-only memory (ROM) for storing micro-code. While the example memory subsystem 110 in FIG. 1 has been illustrated as including the memory subsystem controller 115, in another embodiment of the present disclosure, a memory subsystem 110 does not include a memory subsystem controller 115, and can instead rely upon external control (e.g., provided by an external host, or by a processing device or controller separate from the memory subsystem 110).

In general, the memory subsystem controller 115 can receive commands or operations from the host system 120 and can convert the commands or operations into instructions or appropriate commands to achieve the desired access to the memory devices (e.g., memory devices 130 and/or 140. The memory subsystem controller 115 can be responsible for other operations such as wear leveling operations, garbage collection operations, error detection and error-correcting code (ECC) operations, encryption operations, caching operations, and address translations between a logical address (e.g., logical block address (LBA) and/or namespace) and a physical address (e.g., physical block address) that are associated with the memory devices (e.g., memory devices 130 and/or 140). The memory subsystem controller 115 can further include host interface circuitry to communicate with the host system 120 via the physical host interface. The host interface circuitry can convert the commands received from the host system into command instructions to access the memory devices (e.g., memory devices 130 and/or 140) as well as convert responses associated with the memory devices into information for the host system 120.

The memory subsystem 110 can also include additional circuitry or components that are not illustrated. In some embodiments, the memory subsystem 110 can include a cache or buffer (e.g., DRAM) and address circuitry (e.g., a row decoder and a column decoder) that can receive an address from the memory subsystem controller 115 and decode the address to access the memory devices (e.g., memory devices 130 and/or 140).

In some embodiments, the memory devices (e.g., memory devices 130 and/or 140) include local media controllers 135 that operate in conjunction with memory subsystem controller 115 to execute operations on one or more memory cells of the memory devices (e.g., memory devices 130 and/or 140). An external controller (e.g., memory subsystem controller 115) can externally manage the memory devices (e.g., perform media management operations on the memory devices 130 and/or 140). In some embodiments, a memory device (e.g., memory device 130) is a managed memory device, which is a raw memory device combined with a local controller (e.g., local controller 135) for media management within the same memory device package. An example of a managed memory device is a managed NAND (MNAND) device.

The memory subsystem 110 includes an adaptive memory erasing component 113 that can execute erase operations for memory devices with central row decoders. In some embodiments, the controller 115 includes at least a portion of the adaptive memory erasing component 113. For example, the controller 115 can include a processing device 117 configured to execute instructions stored in local memory 119 for performing the operations described herein. In some embodiments, an adaptive memory erasing component 113 is part of the host system 120, an application, or an operating system.

The adaptive memory erasing component 113 receives erase operations targeting addresses in memory and determines whether the erase operation is targeting a PGB and, if so, which parts of the targeted memory block to erase. Adaptive memory erasing component 113 executes different erase operations depending on whether the target address is a PGB and depending on which portion of the PGB should be erased (e.g., determining which is the “good” portion and/or which is the “bad” portion). Further details with regards to the operations of the adaptive memory erasing component 113 are described below.

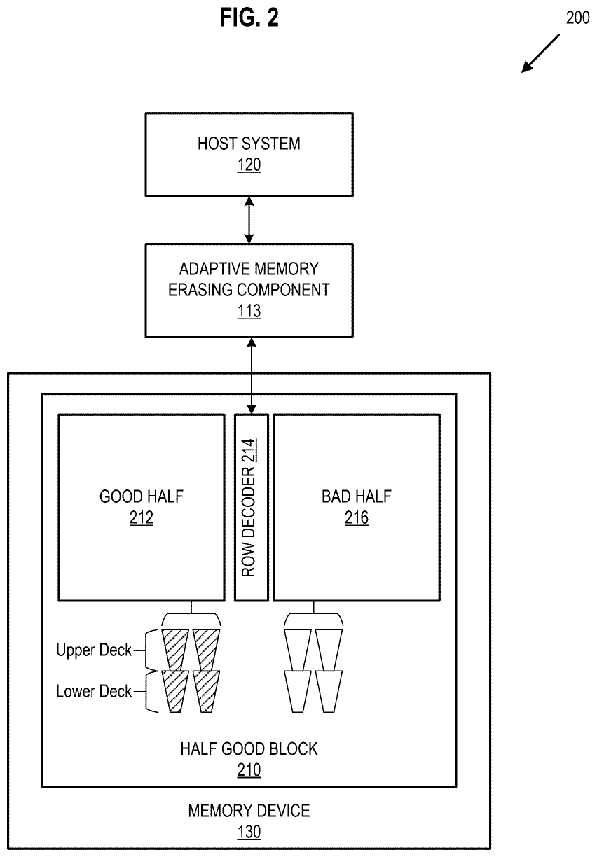

FIG. 2 illustrates another example computing system that includes an adaptive memory erasing component in accordance with some embodiments of the present disclosure. As shown in FIG. 2, computing system 200 includes host system 120, adaptive memory erasing component 113 and memory device 130. Memory device 130 includes half good block 210, which is a memory block with good half 212 separated from bad half 216 by row decoder 214. Each of good half 212 and bad half 216 includes partial wordlines. For example, a single wordline spans across good half 212 and bad half 216 with half of the wordline located in good half 212 and the other half of the wordline located in bad half 216. Row decoder 214 executes operations based on row addresses. Since wordlines are identified by row addresses, row decoder 214 executes operations on a whole wordline based on these row addresses. However, because row decoder 214 physically isolates the partial wordlines in good half 212 and bad half 216, row decoder 214 can apply different voltages to the gates of the partial wordlines for each half of half good block 210, even for the same wordline. Further details regarding applying different voltages for the same wordline are described below.

Although only one memory block (e.g., half good block 210) is illustrated, memory device 130 can include any number of memory blocks that are all good, only left half good, only right half good, or all bad. Additionally, although displayed as halves for the purposes of illustration, partially good blocks of memory device 130 can include any number of subportions. For example, a memory block of memory device 130 can include a left ⅓ portion that is good separated by a row decoder from a middle ⅓ portion that is bad which is in turn separated by a row decoder from a right ⅓ portion that is good. Furthermore, although explained with reference to half good or partially good, the same method can be implemented for a block by deck implementation where the entirety of the memory block is good but only part of the memory block is erased.

In some embodiments, as shown in FIG. 2, adaptive memory erasing component 113 can perform memory operations on only half of half good block 210. For example, the signal from row decoder 214 can be isolated to either of good half 212 and/or bad half 216. As a result, adaptive memory erasing component 113 can perform memory operations on each of good half 212 and bad half 216 independently. For example, as shown in FIG. 2, adaptive memory erasing component 113 can select trim settings to execute an erase operation on good half 212 while leaving bad half 216 in its current state.

As shown in FIG. 2, good half 212 includes upper and lower decks where the upper deck is the upper portion of each of the shaded stacks and the lower deck is the lower portion of each of the shaded stacks. Similarly, bad half 216 includes upper and lower decks where the upper deck is the upper portion of each of the non-shaded stacks and the lower deck is the lower portion of each of the non-shaded stacks. As illustrated in FIG. 2, both decks (e.g., each stack of upper and lower decks) are in the same half of the PGB (e.g., in the good half of the block or the bad half of the block separated by row decoder 214). Accordingly, when row decoder 214 transmits signals to one deck (e.g., upper deck), the signals are also transmitted to the other corresponding deck (e.g., lower deck).

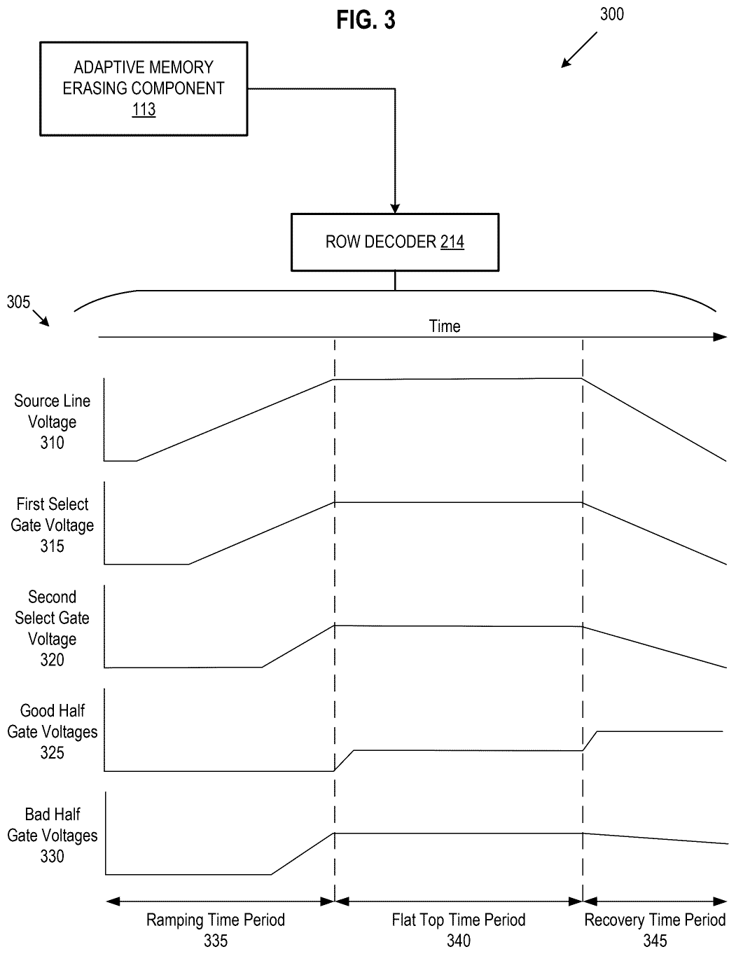

Trim settings affect how row decoder 214 applies voltages to different wordlines of half good block 210. For example, row decoder 214 applies voltages during three time periods for an erase operation: a ramping time period (e.g., ramping time period 335 of FIG. 3), a flat top time period (e.g., flat top time period 340 of FIG. 3), and a recovery time period (e.g., recovery time period 345 of FIG. 3). The ramping time period is the period between the row decoder 214 applying a voltage to a wordline and the wordline reaching the applied voltage. The flat top time period is the time period during which the wordline is at the applied voltage. The recovery time period is the time period when the wordline is recovering from the applied voltage (e.g., returning to a previous voltage value). In order to a perform an erase operation on certain wordlines, row decoders apply a high voltage to the channel for the wordlines while keeping the wordlines grounded (e.g., the gate voltage for the wordlines). This voltage difference causes electrons to be extracted from the charge-stored layer, resulting in an erase operation. In embodiments using replacement gate NAND (RG NAND) technology, the voltage difference between the channel and the gate causes holes to be injected into the charge-stored layer neutralizing the stored electrons. Further details regarding erase operation time periods and voltage waveforms are discussed with reference to FIG. 3.

In some embodiments, adaptive memory erasing component 113 selects trim settings for turning off a switch transistor of row decoder 214, causing the wordline voltage (e.g., gate voltage) for wordlines in bad half 216 to float and follow the channel potential. By following the channel potential, the voltage difference between the gate and channel of the bad half 216 wordlines becomes small, resulting in little to no extraction of electrons and therefore no erase operation. Because row decoder 214 is located within half good block 210 (rather than on an edge), row decoder 214 can apply different voltages to each side (good half 212 or bad half 216) of half good block 210 for the same wordlines. For example, wordlines are positioned as rows of half good block 210 separated by row decoder 214. Row decoder 214 can ground the gate voltage for the partial wordline located in good half 212 while leaving the gate voltage for the partial wordline located in bad half 216 floating. Accordingly, the erase operation will execute on partial wordlines in good half 212 but not the partial wordlines in bad half 216.

In some embodiments, adaptive memory erasing component 113 selects trim settings for applying a bias voltage to wordlines of bad half 216. For example, the selected trim settings cause row decoder 214 to apply a bias voltage to the gates for wordlines of bad half 216. Row decoder 214 applies a bias voltage similar to that of the channel voltage, resulting in little to no voltage difference between the gate and channel for wordlines of bad half 216, resulting in little to no extraction of electrons and therefore no erase operation. For example, row decoder 214 can ground the gate voltage for the partial wordline located in good half 212 while applying a bias voltage to the gate for the partial wordline located in bad half 216. Accordingly, the erase operation will execute on partial wordlines in good half 212 but not partial wordlines in bad half 216.

In some embodiments, adaptive memory erasing component 113 determines the bias voltage based on the density of memory cells. For example, row decoder 214 applies a bias voltage of 4-5 volts for SLCs and applies a bias voltage of 5-6 volts for TLCs. In some embodiments, the bias voltage is predetermined. In some embodiments, adaptive memory erasing component 113 determines the timing of the trim setting based on the density of memory cells. For example, row decoder 214 uses trim settings with a longer flat top time period (e.g., applies voltages for a longer time period) for TLCs than for SLCs.

In some embodiments, adaptive memory erasing component 113 selects the trim settings in response to determining to erase only the left half of half good block 210. For example, adaptive memory erasing component 113 receives a memory command from a host system (e.g., host system 120 of FIG. 1) including a logical address identifying half good block 210. In response to receiving the logical address, adaptive memory erasing component 113 determines that half good block 210 is a PGB and that the good half 212 is the left half. For example, adaptive memory erasing component 113 retrieves a lookup table (e.g., from local memory 119 of FIG. 1) and uses the logical address to determine that the left half of half good block 210 is the good half 212. In one embodiment, the lookup table includes logical addresses for PGBs (e.g., half good block 210) and identifiers indicating which portions of the PGBs are good/bad. In some embodiments, adaptive memory erasing component 113 first determines a physical address using the logical address and uses the physical address with the lookup to determine that the left half of half good block 210 is the good half 212.

In some embodiments, adaptive memory erasing component 113 receives a memory command from a host system (e.g., host system 120 of FIG. 1) identifying only good half 212. For example, adaptive memory erasing component 113 can receive a memory command identifying only a portion of a memory block via an address, address range, etc. In such embodiments, adaptive memory erasing component 113 can determine which portion of the memory block to erase regardless of whether the memory block is a PGB. For example, instead of retrieving a lookup table identifying PGBs by their address, adaptive memory erasing component 113 determines which portion of the memory block to erase using logical to physical mapping.

FIG. 3 illustrates another example computing system 300 that includes adaptive memory erasing component 113 in accordance with some embodiments of the present disclosure. As shown in FIG. 3, adaptive memory erasing component 113 selects trim settings that cause row decoder 214 to apply differing voltages for certain partial wordlines. For example, in the embodiment illustrated by voltage graph 305, source line voltage 310, first select gate voltage 315, second select gate voltage 320, good half gate voltages 325, and bad half gate voltages 330 are applied during an erase operation including a ramping time period 335, flat top time period 340, and a recovery time period 345. Accordingly, in the embodiment illustrated by voltage graph 305, row decoder 214 applies one voltage waveform (good half gate voltages 325) to partial wordlines in a good portion of a memory block (e.g. good half 212 of half good block 210) and applies a different voltage waveform (bad half gate voltages 330) to partial wordlines in a bad portion of the memory block. For example, as explained above, because row decoder 214 is located within half good block 210 (rather than on an edge), row decoder 214 can apply different voltage waveforms to each side (good half 212 or bad half 216) of the same wordlines. Accordingly, row decoder 214 can apply both good half gate voltages 325, and bad half gate voltages 330 to different halves of the same wordline. The voltage waveforms shown in voltage graph 305 are for the purpose of illustration and are not necessarily to scale. Additionally, voltage graph 305 only illustrates voltage waveforms for a portion of an erase operation and for a portion of the total voltage waveforms.

As shown in FIG. 3, source line voltage 310 begins as a low voltage (e.g., a ground voltage) at the beginning of ramping time period 335 and begins ramping to a flat top voltage (e.g., erase voltage) during ramping time period 335. Flat top time period 340 is the time during which the erase operation executes on the selected memory portions. Ramping time period 335 is the time during which the selected memory portions change voltage to meet the flat top voltage for executing the erase operation. For example, the voltages start at a ground voltage and it takes a certain amount of time (e.g., ramping time period 335) for all of the selected memory portions to ramp up from the ground voltage to the flat top voltage required to execute the erase operation. Recovery time period 345 is the time during which the voltages for the selected memory portions return to their original values after the erase operation has been executed at the flat top voltage. Although labeled as source line voltage, the voltage waveform illustrated by source line voltage 310 can be a voltage waveform for a source line signal (SRC) or a voltage waveform for a bit line signal (BL). As shown in FIG. 3, source line voltage 310 ramps up to a flat top voltage during ramping time period 335, remains at the flat top voltage during flat top time period 340, and recovers to a low voltage during recovery time period 345. In some embodiments, the beginning voltage (e.g., beginning of ramping time period 335) and the ending voltage (e.g., ending of recovery time period 345) are a ground voltage. In such embodiments, the flat top voltage (e.g., voltage for duration of flat top time period 340 may be a supply voltage (Vcc).

Voltage graph 305 of FIG. 3 illustrates voltage waveforms for first select gate voltage 315 and second select gate voltage 320. Applying voltages to first select gate voltage 315 and second select gate voltage 320 causes the channel voltage for the selected portions of memory to increase to the flat top voltage. The erase operation executes on the memory block in response to the potential difference between the gate voltage and channel voltage for a memory cell. Accordingly, the erase operation executes on the selected memory portions by applying voltage waveforms such as first select gate voltage 315 and second select gate voltage 320 while grounding the respective gate voltages for those selected memory portions. The voltage waveforms illustrated by first select gate voltage 315 and second select gate voltage 320 can be voltage waveforms for a source-side select gate (SGS) or a drain-side select gate (SGD). Additionally, the waveforms illustrated by first select gate voltage 315 and second select gate voltage 320 are for certain select gates and do not represent all the possible voltage waveforms. As shown in voltage graph 305, first select gate voltage 315 begins ramping from a low voltage (e.g., ground voltage) to a flat top voltage during ramping time period 335, maintains the flat top voltage during flat top time period 340, and recovers back to the low voltage during recovery time period 345. As shown in voltage graph 305, select gates closer to source line (e.g., first select gate voltage 315) begin ramping sooner than select gates farther from the source line (e.g., second select gate voltage 320). In some embodiments, because the partial wordlines represented by first select gate voltage 315 and second select gate voltage 320 are smaller (e.g., include fewer memory cells) than wordlines for implementations without central row decoders, ramping time period 335, flat top time period 340, and/or recovery time period 345 are shorter than for erase operations in implementations without central row decoders. Voltage graph 305 illustrates voltage waveforms for selected gates (e.g., for wordlines subject to an erase operation). Accordingly, first select gate voltage 315 and second select gate voltage 320 do not represent voltage waveforms for gates that are not selected (e.g., for wordlines that are not to be erased).

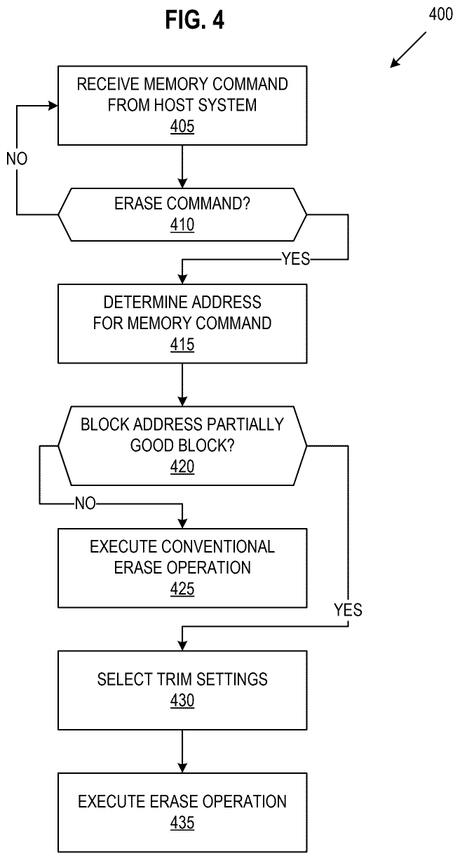

As explained with reference to FIGS. 2 and 4, adaptive memory erasing component 113 can determine to erase only a portion of a memory block. For example, adaptive memory erasing component 113 determines to erase bad half 216 of half good block 210 but determines not erase good half 212 of half good block 210. In such an example, row decoder 214 applies voltages to gates of partial wordlines in good half 212 to produce a voltage waveform resembling good half gate voltages 325 and allows the gates of partial wordlines in bad half 216 to float, causing their voltage waveforms to resemble bad half gate voltages 330. As a result, the erase operation is executed on partial wordlines in good half 212 and not executed on partial wordlines in bad half 216.

In some embodiments, row decoder 214 grounds the gate voltage for partial wordlines located in good half 212. For example, as shown in the voltage waveform for good half gate voltages 325, row decoder 214 grounds the gate voltage for partial wordlines in good half 212 during ramping time period 335. In some embodiments, row decoder 214 applies a debias voltage to the gate voltage for partial wordlines located in good half 212 during flat top time period 340. For example, as shown in the waveform for good half gate voltages 325, row decoder 214 applies a debias voltage to partial wordlines in good half 212 that is less than the erase voltage (e.g., voltage applied to wordlines to be erased). Because the debias voltage (e.g., voltage applied during flat top time period 340) is less than the supply voltage (e.g., voltage applied to the relevant channel during flat top time period 340), the erase operation executes on partial wordlines in good half 212. In some embodiments, row decoder 214 applies a supply voltage to partial wordlines in good half 212 during recovery time period 345. For example, as shown in the waveform for good half gate voltages 325, row decoder 214 applies a supply voltage (Vcc) during recovery time period 345.

In some embodiments, row decoder 214 allows the gate voltage for partial wordlines located in bad half 216 to float. For example, as shown in the voltage waveform for bad half gate voltages 330, the gate voltage for wordlines in bad half 216 follows the channel potential for the relevant channel (e.g., second select gate voltage 320). Accordingly, the voltage waveform for bad half gate voltages 330 mirrors the voltage waveform for the relevant channel during ramping time period 335 and flat top time period 340 while a supply voltage is applied to the channel. Because the voltage waveform for bad half gate voltages 330 mirrors that of second select gate voltage 320, there is little to no voltage difference between the gate and channel for partial wordlines in bad half 216. Accordingly, the erase operation does not execute on partial wordlines in bad half 216. During recovery time period 345, when second select gate voltage 320 is grounded, the voltage waveform for bad half gate voltages 330 will slowly decay to ground (e.g., gradual decrease).

In some embodiments, row decoder 214 applies a bias gate voltage for partial wordlines located in bad half 216. For example, as shown in the voltage waveform for bad half gate voltages 330, row decoder 214 may apply a voltage to the gate voltage for wordlines in bad half 216 similar to that of the voltage applied to the relevant channel (e.g., second select gate voltage 320). Because the bias voltage applied to partial wordlines in bad half 216 is the same as the voltage applied to second select gate voltage 320, there is little to no voltage difference between the gate and channel for partial wordlines in bad half 216 and the erase operation does not execute.

FIG. 4 is a flow diagram of an example method 400 to adaptively erase memory devices with central row decoders, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the adaptive memory erasing component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, the processing device receives a memory command from a host system. For example, adaptive memory erasing component 113 receives a memory command from host system 120 of FIG. 1. In some embodiments, the memory command is one of a program command, read command, or erase command. For example, host system 120 sends an erase command to memory subsystem 110 to erase a portion of memory in memory device 130. In some embodiments, the memory command includes an address. For example, the memory command includes a logical address identifying a block of memory device 130 that is the target of the memory operation.

At operation 410, the processing device determines whether the received memory command is an erase command. For example, adaptive memory erasing component 113 determines whether the memory command received is a program command, read command, erase command, etc. If the processing device determines that the received memory command is an erase command, the method 400 proceeds to operation 415. If the processing device determines that the received memory command is not an erase command (e.g., the received memory command is a program or read command), the method 400 returns to operation 405 and waits for another memory command from the host system.

At operation 415, the processing device determines an address for the received erase command. For example, the memory command includes a logical address identifying a portion of memory to be erased by adaptive memory erasing component 113 and adaptive memory erasing component 113 determines a physical address using the logical address. In some embodiments, the erase command identifies a portion of a block to erase (e.g., good half 212 or bad half 216 of half good block 210 of FIG. 2). In such examples, although described below in terms of good half versus bad half, this can be interpreted as identified portion (e.g., good half) and non-identified portion (e.g., bad half). In such embodiments, the processing device can erase only a portion of the memory block regardless of whether the memory block is a PGB.

At operation 420, the processing device determines whether the determined address is for a PGB. For example, adaptive memory erasing component 113 retrieves a lookup table from local memory 119 and determines whether the received address is for a PGB using the lookup table. In some embodiments, the processing device also determines which portion or portions of the PGB to erase. For example, in the embodiment shown in FIG. 2, adaptive memory erasing component 113 determines that the left portion of half good block 210 is the good half 212 and therefore determines to erase good half 212. If the processing device determines that the determined address is for a partially good block, the method 400 proceeds to operation 430. If the processing device determines that the determined address is not for a partially good block, the method 400 proceeds to operation 425.

At operation 425, the processing device executes a conventional erase operation. For example, adaptive memory erasing component 113 executes an erase operation with conventional trim settings on the entirety of the block identified by the address. These conventional trim settings cause, for example, a row decoder to apply a channel voltage while grounding the gate voltage for wordlines of the entirety of the block (e.g., both sides of the row decoder), resulting in the execution of an erase operation on the entirety of the block.

At operation 430, the processing device selects trim setting for the partially good block. For example, adaptive memory erasing component 113 retrieves a lookup table (e.g., from local memory 119) and determines that the block is PGB and that the left subportion of the block should be erased as described above with reference to operation 420. In some embodiments, adaptive memory erasing component 113 selects trim settings causing the central row decoder to ground gate voltages for partial wordlines in the good half while letting the gate voltages for partial wordlines in the bad half (e.g., the half not to be erased) to float, resulting in little to no voltage difference between the gate and channel voltages and therefore no erase operation for those partial wordlines. In some embodiments, adaptive memory erasing component 113 selects trim settings causing the central row decoder to ground the gate voltage for the partial wordlines in the good half while applying a bias voltage to the gates for partial wordlines in the bad half, resulting in little to no voltage difference between the gate and channel voltages for the partial wordlines in the bad half and therefore no erase operation for those partial wordlines. Further details with regard to selecting trim setting are explained with reference to FIG. 2.

At operation 435, the processing device executes the erase operation. For example, adaptive memory erasing component 113 causes row decoder 214 to execute the erase operation using the selected trim settings.

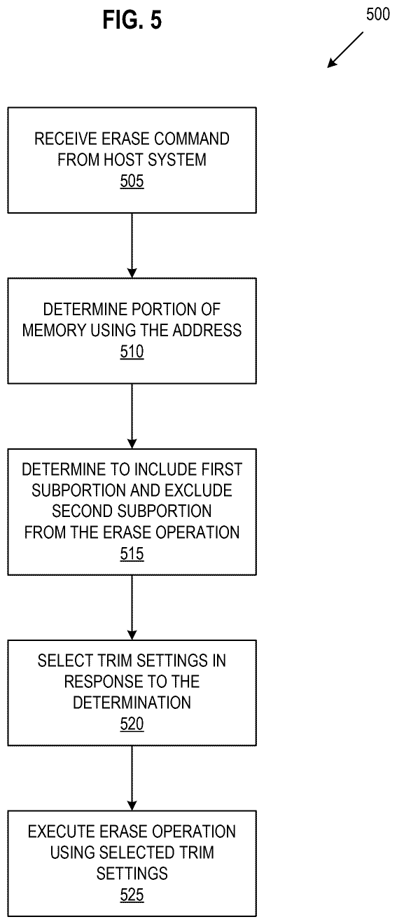

FIG. 5 is a flow diagram of an example method 500 to adaptively erase memory devices with central row decoders, in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the adaptive memory erasing component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 505, the processing device receives an erase command from the host system. For example, adaptive memory erasing component 113 receives an erase command from host system 120. In some embodiments, the erase command includes an address. For example, the received erase command includes a logical address identifying a portion of memory that is the target of the erase command. Further details regarding receiving an erase command are described with reference to FIGS. 2 and 4.

At operation 510, the processing device determines a portion of memory using the address of the erase command. For example, adaptive memory erasing component 113 receives the erase command including the logical address and determines the portion of memory as a portion of memory identified by a physical address identified using the logical address. In some embodiments, the portion of memory includes multiple subportions. For example, the portion of memory is a memory block broken into two subportions with a central row decoder separating the subportions. Each of these subportions includes partial wordlines where whole wordlines are divided into partial wordlines by the central row decoder. Further details regarding determining the portion of memory are described with reference to FIGS. 2 and 4.

At operation 515, the processing device determines to include a first subportion in an erase operation and exclude a second subportion of the portion of memory from the erase operation. For example, adaptive memory erasing component 113 retrieves a lookup table using the address (e.g., logical and/or physical address) and determines which part of the memory block to include in the erase operation using the lookup table and the address. In one example, adaptive memory erasing component 113 determines that the left half of half good block 210 is the good half 212 and therefore determines to include good half 212 in the erase operation and to exclude bad half 216 from the erase operation. Further details regarding determining to erase the subportion are described with reference to FIGS. 2 and 4.

At operation 520, the processing device selects trim settings in response to the determination. For example, adaptive memory erasing component 113 selects trim settings for row decoder 214 based on which subportion is being erased as described with reference to operation 515. In some embodiments, adaptive memory erasing component 113 selects trim settings causing row decoder 214 to ground the gate voltages for partial wordlines in the subportion to be erased while letting the gate voltages for partial wordlines in the subportion that should not be erased to float. In some embodiments, adaptive memory erasing component 113 selects trim settings causing row decoder 214 to ground the gate voltages for partial wordlines in the subportion that should be erase while applying a bias voltage to the gates for partial wordlines in the subportion that should not be erased. Further details regarding selecting trim settings are described with reference to FIGS. 2-4.

At operation 525, the processing device executes the erase command using the selected trim settings. For example, adaptive memory erasing component 113 causes row decoder 214 to execute the erase operation using the selected trim settings.

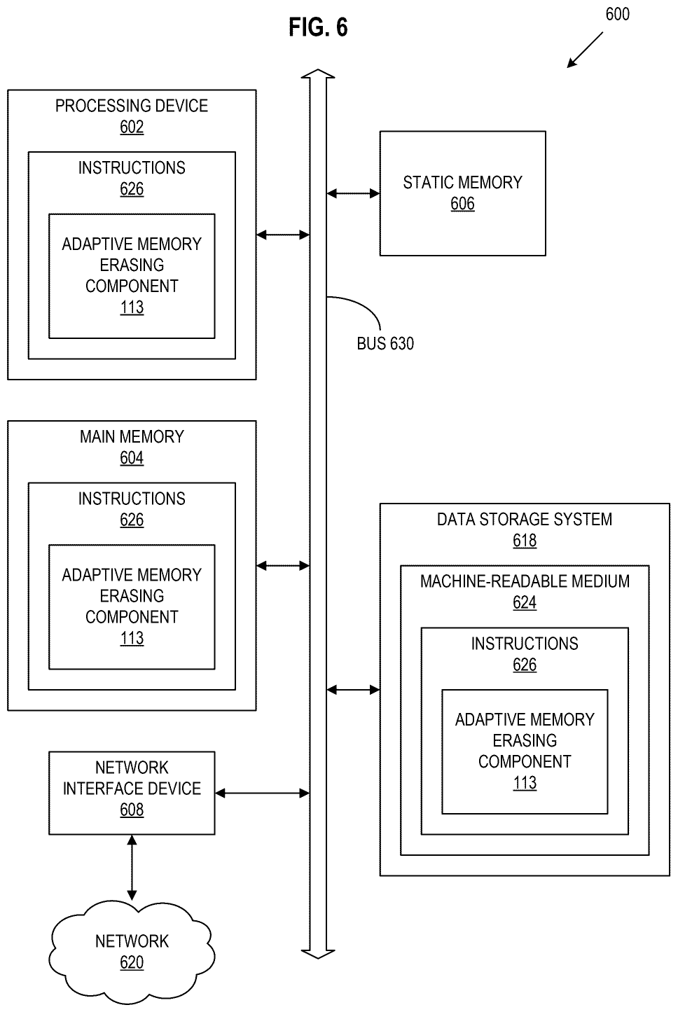

FIG. 6 illustrates an example machine of a computer system 600 within which a set of instructions for causing the machine to perform any one or more of the methodologies discussed herein can be executed. In some embodiments, the computer system 600 can correspond to a host system (e.g., the host system 120 of FIG. 1) that includes, is coupled to, or utilizes a memory subsystem (e.g., the memory subsystem 110 of FIG. 1) or can be used to perform the operations of a controller (e.g., to execute an operating system to perform operations corresponding to the adaptive memory erasing component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a smart device, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random-access memory (DRAM) such as synchronous DRAM (SDRAM) or Rambus DRAM (RDRAM), etc.), a static memory 606 (e.g., flash memory, static random-access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626, constituting machine-readable storage media, can also reside, completely or at least partially, within the main memory 604 and/or within the processing device 602 during execution thereof by the computer system 600, the main memory 604 and the processing device 602. The machine-readable storage medium 624, data storage system 618, and/or main memory 604 can correspond to the memory subsystem 10 of FIG. 1.

In one embodiment, the instructions 626 include instructions to implement functionality corresponding to an adaptive memory erasing component (e.g., adaptive memory erasing component 113 of FIG. 1). While the machine-readable storage medium 624 is shown in an example embodiment to be a single medium, the term “machine-readable storage medium” should be taken to include a single medium or multiple media that store the one or more sets of instructions (e.g., instructions 626). The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. For example, a computer system or other data processing system, such as the controller 115, may carry out the computer-implemented methods 400 and 500 in response to its processor executing a computer program (e.g., a sequence of instructions) contained in a memory or other non-transitory machine-readable storage medium. Such a computer program can be stored in a computer readable storage medium, such as, but not limited to, any type of disk including floppy disks, optical disks, CD-ROMs, and magnetic-optical disks, read-only memories (ROMs), random-access memories (RAMs), EPROMs, EEPROMs, magnetic or optical cards, or any type of media suitable for storing electronic instructions coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
receiving, from a host system, an erase command for a memory device including a plurality of portions, wherein each of the plurality of portions includes a row decoder and wherein the erase command includes an address;
determining a portion of memory of the plurality of portions using the address, wherein the row decoder divides the portion of memory into a plurality of subportions including a first subportion and a second subportion, each of the plurality of subportions comprising a plurality of partial wordlines;
determining to include the first subportion in an erase operation and exclude the second subportion from the erase operation;
selecting trim settings in response to the determination to include the first subportion and exclude the second subportion; and
executing the erase operation on the plurality of partial wordlines in the first subportion but not executing the erase operation on the plurality of partial wordlines in the second subportion based on the selected trim settings.

2. The method of claim 1, wherein executing the erase operation on the plurality of partial wordlines in the first subportion but not the plurality of partial wordlines in the second subportion comprises turning off a switch transistor of the row decoder for the plurality of partial wordlines in the second subportion.

3. The method of claim 1, wherein executing the erase operation on the plurality of partial wordlines in the first subportion but not the plurality of partial wordlines in the second subportion comprises applying a bias voltage to the row decoder for plurality of partial wordlines in the second subportion.

4. The method of claim 1, wherein determining to include the first subportion in the erase operation and exclude the second subportion from the erase operation comprises retrieving an identifier for the portion of memory from a lookup table using the address, wherein the identifier indicates the first subportion is good and the second subportion is bad.

5. The method of claim 1, further comprising:
receiving, from the host system, a second erase command including a second address;
determining a second portion of memory of the plurality of portions using the second address;
determining that the second portion of memory is not a partially good block using the second address; and
executing, in response to the determination that the second portion of memory is not a partially good block, a second erase operation using trim settings to erase an entirety of the second portion of memory.

6. The method of claim 5, wherein the second portion of memory includes a plurality of subportions and wherein executing the second erase operation comprises executing the second erase operation with the same trim settings for the plurality of subportions.

7. The method of claim 1, wherein the erase command identifies the first subportion and excludes the second subportion and wherein determining include the first subportion in the erase operation and exclude the second subportion from the erase operation is in response to the erase command identifying the first subportion and excluding the second subportion.

8. A non-transitory computer-readable storage medium comprising instructions that, when executed by a processing device, cause the processing device to:
receive, from a host system, an erase command for a memory device including a plurality of portions, wherein each of the plurality of portions includes a row decoder and wherein the erase command includes an address;
determine a portion of memory of the plurality of portions using the address, wherein the row decoder divides the portion of memory into a plurality of subportions including a first subportion and a second subportion, each of the plurality of subportions comprising a plurality of partial wordlines;
determine to include the first subportion in an erase operation and exclude the second subportion from the erase operation;
select trim settings in response to the determination to include the first subportion and exclude the second subportion; and
execute the erase operation on the plurality of partial wordlines in the first subportion but not executing the erase operation on the plurality of partial wordlines in the second subportion based on the selected trim settings.

9. The non-transitory computer-readable storage medium of claim 8, wherein executing the erase operation on the plurality of partial wordlines in the first subportion but not the plurality of partial wordlines in the second subportion comprises turning off a switch transistor of the row decoder for the plurality of partial wordlines in the second subportion.

10. The non-transitory computer-readable storage medium of claim 8, wherein executing the erase operation on the plurality of partial wordlines in the first subportion but not the plurality of partial wordlines in the second subportion comprises applying a bias voltage to the row decoder for plurality of partial wordlines in the second subportion.

11. The non-transitory computer-readable storage medium of claim 8, wherein determining to include the first subportion in the erase operation and exclude the second subportion from the erase operation comprises retrieving an identifier for the portion of memory from a lookup table using the address, wherein the identifier indicates the first subportion is good and the second subportion is bad.

12. The non-transitory computer-readable storage medium of claim 8, wherein the processing device is further to:
receive, from the host system, a second erase command including a second address;
determine a second portion of memory of the plurality of portions using the second address;
determine that the second portion of memory is not a partially good block using the second address; and
execute, in response to the determination that the second portion of memory is not a partially good block, a second erase operation using trim settings to erase an entirety of the second portion of memory.

13. The non-transitory computer-readable storage medium of claim 12, wherein the second portion of memory includes a plurality of subportions and wherein executing the second erase operation comprises executing the second erase operation with the same trim settings for the plurality of subportions.

14. The non-transitory computer-readable storage medium of claim 8, wherein the erase command identifies the first subportion and excludes the second subportion and wherein determining to include the first subportion in the erase operation and exclude the second subportion from the erase operation is in response to the erase command identifying the first subportion and excluding the second subportion.

15. A system comprising:
a plurality of memory devices; and
a processing device, operatively coupled with the plurality of memory devices, to:
receive, from a host system, an erase command for a memory device including a plurality of portions, wherein each of the plurality of portions includes a row decoder and wherein the erase command includes an address;
determine a portion of memory of the plurality of portions using the address, wherein the row decoder divides the portion of memory into a plurality of subportions including a first subportion and a second subportion, each of the plurality of subportions comprising a plurality of partial wordlines;
determine to include the first subportion in an erase operation and exclude the second subportion from the erase operation;
select trim settings in response to the determination to include the first subportion and exclude the second subportion;
execute the erase operation on the plurality of partial wordlines in the first subportion but not executing the erase operation on the plurality of partial wordlines in the second subportion based on the selected trim settings;
receive, from the host system, a second erase command including a second address;
determine a second portion of memory of the plurality of portions using the second address;
determine that the second portion of memory is not a partially good block using the second address; and
execute, in response to the determination that the second portion of memory is not a partially good block, a second erase operation using trim settings to erase an entirety of the second portion of memory.

16. The system of claim 15, wherein executing the erase operation on the plurality of partial wordlines in the first subportion but not the plurality of partial wordlines in the second subportion comprises turning off a switch transistor of the row decoder for the plurality of partial wordlines in the second subportion.

17. The system of claim 15, wherein executing the erase operation on the plurality of partial wordlines in the first subportion but not the plurality of partial wordlines in the second subportion comprises applying a bias voltage to the row decoder for plurality of partial wordlines in the second subportion.

18. The system of claim 15, wherein determining to include the first subportion in the erase operation and exclude the second subportion from the erase operation comprises retrieving an identifier for the portion of memory from a lookup table using the address, wherein the identifier indicates the first subportion is good and the second subportion is bad.

19. The system of claim 18, wherein the second portion of memory includes a plurality of subportions and wherein executing the second erase operation comprises executing the second erase command with the same trim settings for the plurality of subportions.

20. The system of claim 15, wherein the erase command identifies the first subportion and excludes the second subportion and wherein determining to include the first subportion in the erase operation and exclude the second subportion from the erase operation is in response to the erase command identifying the first subportion and excluding the second subportion.
